(19) United States
(12) Patent Application Publication
(10) Pub. No.: US 2015/0261119 A1
(43) Pub. Date: Sep. 17, 2015

(54) EXPOSURE DEVICE AND IMAGE FORMING APPARATUS

(71) Applicant: CANON KABUSHIKI KAISHA, Tokyo (JP)

(72) Inventors: Noa Sumida, Utsunomiya-shi (JP); Takeyoshi Saiga, Tokyo (JP); Yu Miyajima, Utsunomiya-shi (JP); Nobutaka Mizuno, Tokyo (JP); Yojiro Matsuda, Kawasaki-shi (JP)

(21) Appl. No.: 14/433,595

(22) PCT Filed: Sep. 27, 2013
(86) PCT No.: PCT/JP2013/077015

§ 371 Date: Apr. 3, 2015

(30) Foreign Application Priority Data
Oct. 5, 2012 (JP) 2012-222888
Sep. 11, 2013 (JP) 2013-188028

(51) Int. Cl. B41J 2/385

(52) U.S. Cl. CPC G03G 15/0409

(57) ABSTRACT

An exposure device includes an element array that includes a plurality of organic electroluminescent elements and a lens array optical system that uses a lens array that includes a plurality of lenses, which forms images of light from the element array on a photosensitive body. In the exposure device, each electroluminescent element has a first electrode disposed on a light emitting side, a second electrode disposed on a light reflecting side, and a light emitting layer. In the exposure device, in each organic electroluminescent element, an optical path length L₁ between a light emitting position of the light emitting layer and the second electrode is an optical path length within ±10% of an optical path length at which variation in light amount during light exposure is minimized.

### TECHNICAL FIELD

The present invention relates to exposure devices and image forming apparatuses such as copiers and printers that use the electrophotographic method.

### BACKGROUND ART

Electrophotographic printing apparatuses equipped with a light source that includes organic EL elements, which are arranged in an array and serve as light emitting elements for a light exposure head, have been proposed. An electrophotographic printing apparatus typically uses a converging lens array optical system for condensing light from a light source on a photosensitive drum.

In an optical writing device using such converging lens array, there is a problem in that an imaging light amount of light emitting elements varies depending on the positional relationships between the light emitting elements and the lens arrays (the pitch of the light emitting elements is smaller than the pitch of the lenses in lens arrays). Thus, several methods have been proposed to reduce the variation in light amount. For example, according to a technology described in PTL 1, an optical element is provided between the light emitting element and the lens array so as to refract a light component, which is emitted from the light emitting element, perpendicular to a substrate to a direction other than a direction perpendicular to the substrate. With this structure, the light amounts of light condensed on a photosensitive drum are averaged, thereby reducing non-uniformity of image due to variation in light amount.

### CITATION LIST

### Patent Literature

PTL 1 Japanese Patent Laid-Open No. 2007-210105

### SUMMARY OF INVENTION

### Technical Problem

However, when the optical element as described above is provided as a measure against the problem, the number of production steps increases and the cost is also increased.

The present invention is proposed in view of the above-described problem. The present invention reduces non-uniformity of image due to variation in light amount caused by a lens array in an electrophotographic printing apparatus using an organic EL element array as a light exposure head without additional production processes.

### Solution to Problem

According to a first aspect of the present invention, an exposure device includes an element array that includes a plurality of organic electroluminescent elements and a lens array optical system that uses a lens array that includes a plurality of lenses, which form images of light from the element array on a photosensitive body. In the exposure device, each electroluminescent element has a first electrode disposed on a light emitting side, a second electrode disposed on a light reflecting side, and a light emitting layer. In the exposure device, in each organic electroluminescent element, an optical path length L₁ between a light emitting position of the light emitting layer and the second electrode is an optical path length within ±10% of an optical path length at which variation in light amount during light exposure is minimized.

According to a second aspect of the present invention, an exposure device includes an element array that includes a plurality of organic electroluminescent elements and a lens array optical system that uses a lens array that includes a plurality of lenses, which form images of light from the element array on a photosensitive body. In the exposure device, each electroluminescent element has a first electrode disposed on a light emitting side, a second electrode disposed on a light reflecting side, and a light emitting layer. In the exposure device, the first electrode has a metal film or a dielectric mirror, and in each organic electroluminescent element, an optical path length L₂ between the first electrode and the second electrode is an optical path length within ±5% of an optical path length at which variation in light amount during light exposure is minimized.

According to a third aspect of the present invention, an image forming apparatus includes either of the above-described exposure devices, a photosensitive body, on a surface of which a latent image is formed by using the exposure device, and a charging unit that charges the photosensitive body.

### Advantageous Effects of Invention

With the above-described structure according to the present invention, by utilizing the directivity (angular distribution) of the radiant intensity of the organic EL element, variation in light amount in an image of the light emitting element depending on the positional relationship between the light emitting element and the lens array can be reduced in an optical writing device that uses a converging lens array. The angular distribution of the radiant intensity of light emission performed by the light emitting element can be realized by, for example, adjusting the film thickness of an organic layer. Since only adjustment of the film thickness of the organic layer is performed, a printing apparatus can be produced in the number of steps in production similar to that of a typical production process without a significant increase in the cost. Thus, the printing apparatus, in which non-uniformity of image due to variation in light amount is decreased, can be provided.

### BRIEF DESCRIPTION OF DRAWINGS

FIG. 1A illustrates an image forming apparatus, and FIG. 1B illustrates a color image forming apparatus.

FIG. 2A illustrates a lens array optical system (section in main array direction), FIG. 2B illustrates the lens array optical system (section in sub array direction), and FIG. 2C illustrates the lens array optical system (front surface).

FIG. 3 is a general sectional view of an organic EL element according to an embodiment of the present invention.

FIG. 4 illustrates a lens optical unit (sections in main and sub array direction).

FIG. 5A illustrates an imaging light beam of a light emitting position A, FIG. 5B illustrates an imaging light beam of a light emitting position B, and FIG. 5C illustrates an imaging light beam of a light emitting position C.

FIG. 6 is a graph where line (A) indicates an angle-by-angle intensity ratio of the light emitting position A without consideration for an angular distribution of the radiant intensity, line (B) indicates an angle-by-angle intensity ratio of the light emitting position B without consideration for the angular distribution of the radiant intensity, and line (C) indicates an angle-by-angle intensity ratio of the light emitting position C without consideration for the angular distribution of the radiant intensity.

FIG. 7 is a graph illustrating the relationships among an optical path length L₁, an imaging light amount, and variation in light amount according to a first embodiment.

FIG. 8 is a graph illustrating comparison of the imaging light amount among the light emitting positions A, B, and C according to the first embodiment.

FIG. 9 is a graph illustrating the relationships among an optical path length L₂, an imaging light amount, and variation in light amount according to a second embodiment.

FIG. 10 is a graph illustrating comparison of the imaging light amount among the light emitting positions A, B, and C according to the second embodiment.

FIG. 11 is a graph illustrating the relationships among an optical path length L₁, an imaging light amount, and variation in light amount according to the second embodiment.

### DESCRIPTION OF EMBODIMENTS

The exposure device according to the present invention serves as a linear light source, to which a photosensitive drum is exposed, and includes an element array and a lens array optical system. The element array includes a plurality of linearly arranged organic electroluminescent (EL) elements. The lens array optical system is disposed so as to oppose the light emitting elements and forms images of light emitted from the light emitting elements on the photosensitive drum. The organic EL elements each include a first electrode on the light emitting side and a second electrode on the light reflecting side (for example, the first electrode is an anode and the second electrode is a cathode), and a light emitting layer. Furthermore, in order to reduce non-uniformity of the amount of light due to a lens array, in the organic EL element, the optical path length between a light emitting position and the second electrode or the optical path length between the first and second electrodes is set so as to satisfy a specific relationship.

Embodiments of a printing apparatus according to the present invention generally having the above-described structure will be described below with reference to the drawings. Unless specifically described or illustrated in the present description, well-known or popular technologies in applicable fields are applied. Also, the embodiments described below are examples of embodiments according to the invention and do not limit the invention.

### Image Forming Apparatus

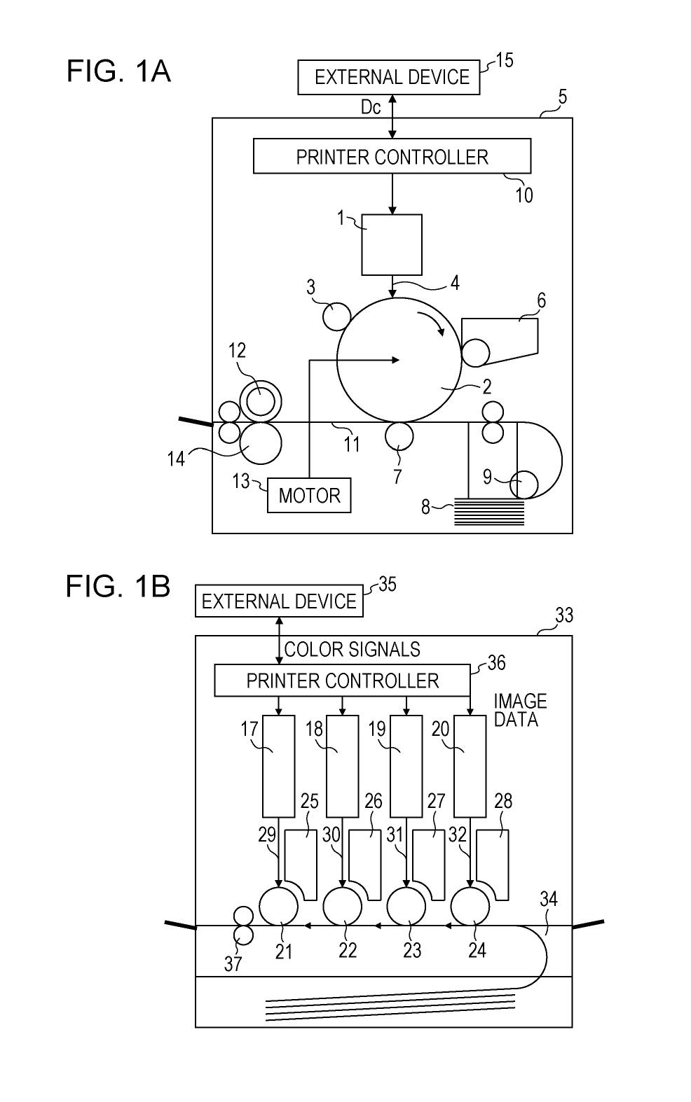

FIG. 1A is a general sectional view of an embodiment of an image forming apparatus according to the present invention taken in a sub scanning direction. Referring to FIG. 1A, reference numeral 5 denotes the image forming apparatus. The image forming apparatus 5 receives code data Dc from an external device 15 such as a personal computer. The code data Dc is converted to image data (dot data) Di by a printer controller 10 disposed in the apparatus. This image data Di is input to an exposure unit 1 having a structure described in a first embodiment. The exposure unit (exposure device) 1 emits exposure light 4 modulated in accordance with the image data Di. A photosensitive surface of a photosensitive drum 2 is exposed to the exposure light 4.

The photosensitive drum 2 that serves as an electrostatic latent image carrying body (photosensitive body) is rotated clockwise by a motor 13. As the photosensitive drum 2 is rotated, the photosensitive surface of the photosensitive drum 2 is moved in a second direction with respect to the exposure light 4. A charger roller 3, which causes the surface of the photosensitive drum 2 to be uniformly charged, is disposed on the upper side of the photosensitive drum 2 so as to be in contact with the surface of the photosensitive drum 2. The surface of the photosensitive drum 2 having been charged by the charger roller 3 is irradiated with the exposure light 4 from the exposure unit 1.

As described above, the exposure light 4 is modulated in accordance with the image data Di. By irradiating the surface of the photosensitive drum 2 with this exposure light 4, an electrostatic latent image is formed on the surface of the photosensitive drum 2. The electrostatic latent image is developed into a toner image by a developing device 6, which is disposed so as to be in contact with the photosensitive drum 2 on the downstream side of the position irradiated with the exposure light 4 in the rotational direction of the photosensitive drum 2.

The toner image developed by the developing device 6 is transferred onto a sheet 11 that serves as a transfer target member on the lower side of the photosensitive drum 2 by a transfer roller 7, which is disposed so as to oppose the photosensitive drum 2. Although the sheet 11 is loaded in a sheet cassette 8 disposed in front of (on the right side in FIG. 1A) the photosensitive drum 2, the sheet 11 may instead be manually fed. A sheet feed roller 9 is disposed at an end portion of the sheet cassette 8 so as to feed the sheet 11 in the sheet cassette 8 to a conveying path.

The sheet 11, onto which the unfixed toner image has been transferred as described above, is further conveyed to a fixing device, which is disposed on the rear side (on the left side in FIG. 1A) of the photosensitive drum 2. The fixing device includes a fixing roller 12 and a pressure roller 14. The fixing roller 12 includes a fixing heater (not shown) therein. The pressure roller 14 is disposed so as to be in pressure contact with the fixing roller 12. The sheet 11 conveyed from a transfer unit is heated while being pressurized in a pressure contact portion between the fixing roller 12 and the pressure roller 14, thereby fixing the unfixed toner image onto the sheet 11.

Although it is not illustrated in FIG. 1A, the printer controller 10 controls the motor 13 and other components and the like of the image forming apparatus in addition to control of the data conversion as described above.

### Color Image Forming Apparatus

FIG. 1B is a general schematic diagram of a color image forming apparatus according to an embodiment of the present invention. In the present embodiment, a color image forming apparatus 33 is of a tandem-type, in which four exposure devices are arranged so as to record image information in parallel on the surface of a respective photosensitive drums, which each serve as an image carrying body. The color image forming apparatus 33 includes exposure devices 17, 18, 19, and 20 (exposure devices), photosensitive drums 21, 22, 23, and 24, which each serve as the image carrying body, developing devices 25, 26, 27, and 28, and a conveying belt 34.

Referring to FIG. 1B, the color image forming apparatus 33 receives red (R), green (G), and blue (B) color signals from an external device 35 such as a personal computer. These color signals are converted to cyan (C), magenta (M), yellow (Y), and black (B) image data (dot data) by a printer controller 93 disposed in the apparatus. Each of the cyan, magenta, yellow, and black image data is input to a corresponding one of the exposure devices 17, 18, 19, and 20. These exposure devices 17, 18, 19, and 20 emit exposure light 29, 30, 31, and 32 modulated in accordance with the corresponding image data. Photosensitive surfaces of the photosensitive drums 21, 22, 23, and 24 are exposed to the corresponding one of the exposure light 29, 30, 31, and 32.

In the color image forming apparatus 33 according to the present embodiment, four exposure devices 17, 18, 19, and 20, which each correspond to corresponding one of cyan (C), magenta (M), yellow (Y), and the black (B) colors, are arranged so as to record image signals (image information) in parallel on the respective photosensitive drums 21, 22, 23, and 24, thereby printing a color image at high speed.

In the color image forming apparatus 33 according to the present embodiment, as described above, four exposure devices 17, 18, 19, and 20 use the exposure light 29, 30, 31, and 32 in accordance with the corresponding image data so as to form latent images for the colors on the surfaces of the respective photosensitive drums 21, 22, 23, and 24. After that, multiple-transfer onto a recording medium is performed so as to form a full-color image.

The external device 35 may use, for example, a color image scanning device equipped with a CCD sensor. In this case, this color image scanning device and the color image forming apparatus 33 are parts of a color digital copier.

### Exposure Unit

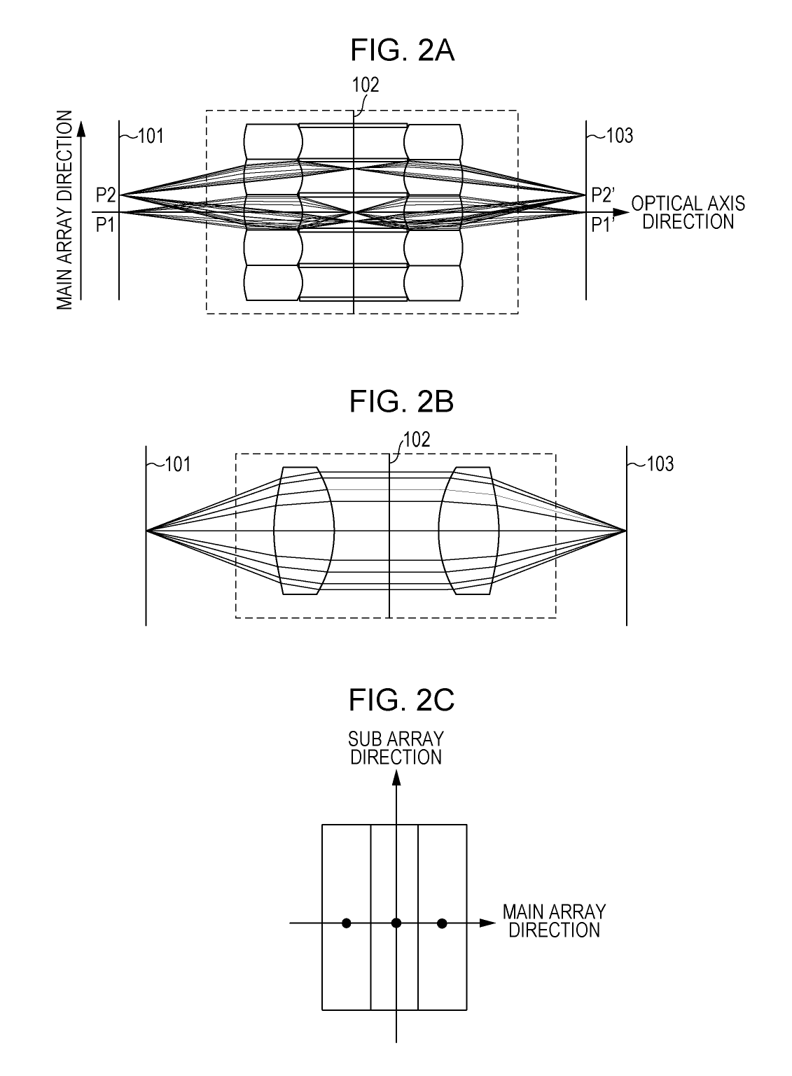

The exposure unit has a structure as illustrated in FIGS. 2A to 2C. The exposure unit includes an element array and a lens array optical system 102. The element array, which includes a plurality of organic EL elements equally spaced in a main array direction, serves as a light source unit 101. The lens array optical system 102 includes single-row lens optical units arranged in a sub array direction. The lens optical units each form a unity-magnification erect image with respect to the main array direction and an inverted image with respect to the sub array direction. Filled circles in FIG. 2C indicate optical axes of the lens optical units.

Light emitting points of the light source unit 101 are spaced apart from one another by tens of μm, which is sufficiently tightly arranged compared to the lens optical units spaced apart from one another by at least hundreds of μm. Thus, in the following description, the positions of the light emitting points discussed herein are regarded as continuous with one another. Since each lens optical unit forms a unity-magnification erect image with respect to the main array direction, a light beam emitted from the light source unit 101 is condensed to a single point on an image plane 103 of a photosensitive body even after the light beams have passed through a plurality of the lens optical units arranged in the array direction. For example, referring to FIG. 2A, a light beam from a light emitting point P1 is condensed to P1′ and a light beam from a light emitting point P2 is condensed to P2′. Because of this characteristic, light exposure corresponding to light emission performed by the light source unit is possible.

### Structure of Organic EL Element

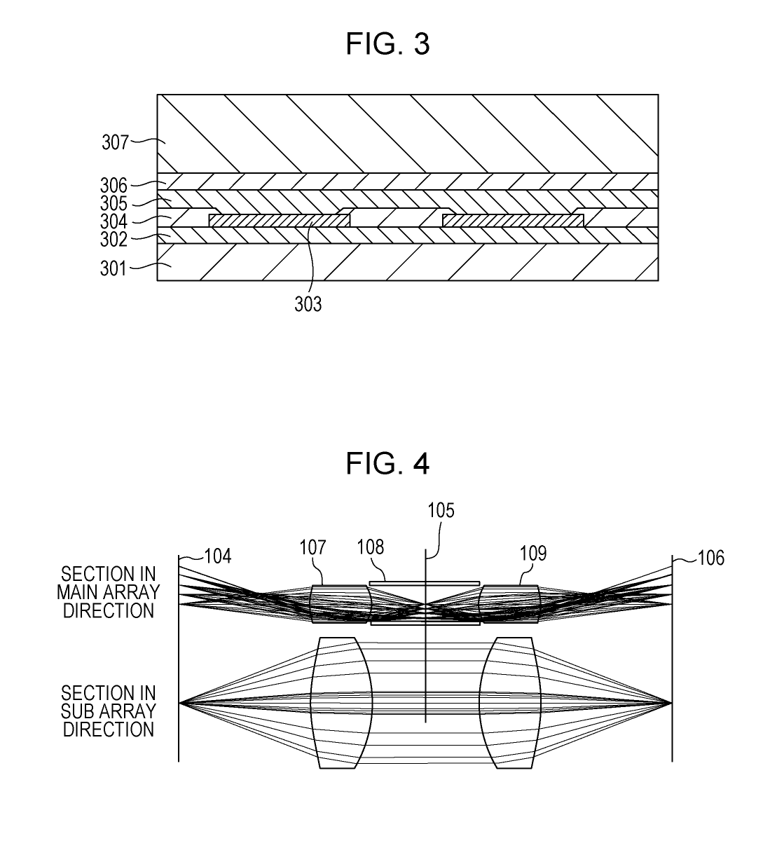

Next, the structure of each of the organic EL elements formed on an element array substrate is specifically described. FIG. 3 is a general sectional view of the organic EL element. The present organic EL element is of a top emission type that emits light outward (upper side in FIG. 3) from the surface of the substrate. Despite this, regarding the present invention, the structure of the EL element is not limited to the top emission type. Bottom emission type elements may be used.

Specifically, the element substrate includes a glass substrate 301 and a base layer 302, which is formed on the glass substrate 301. Switching elements such as thin film transistors and metal-insulator-metal (MIM) elements may be formed in the base layer 302. The substrate 301 may use a silicon substrate or the like. The organic EL element includes an anode (second electrode on the light reflecting side) 303, an organic EL layer 305 provided on the anode 303, and a cathode (first electrode on the light emitting side) 306 provided on the organic EL layer 305. Here, the organic EL layer 305 contains at least a light emitting layer. The organic EL layer 305 may be a layered body including a plurality of layers. Examples of the layer structures of the organic EL layer 305 include a four-layer structure that includes a hole transport layer, the light emitting layer, an electron transport layer, and an electron injection layer, and a three-layer structure that includes the hole transport layer, the light emitting layer, and the electron transport layer. Well known materials may be used as the materials of the organic EL layer 305 (organic light emitting material, hole transport material, electron transport material, electron injection material, and the like). A separation wall 304 is formed between two adjacent organic EL elements so as to prevent the anode and cathode from making a short-circuit.

The anodes 303 are linearly arranged pixel by pixel on the glass substrate 301, and one common cathode 306 is provided for the plurality of organic EL elements. Transistors (not shown) that activate the organic EL elements are provided on the glass substrate 301.

A protective layer 307 is formed on the cathode 306 so as to protect the organic EL layer 305 from oxygen and water in air. The protective layer 307 is formed of an inorganic material such as silicon nitride (SiN) or silicon oxynitride (SiON). The thickness of the inorganic film is preferably from 0.1 μm to 10 μm, and the inorganic film can be formed by a chemical vapor deposition (CVD) method. In the case where the surface of the protective layer 307 has irregularities conforming to the shape of the base, the protective layer 307 may be a multilayer that includes inorganic and organic materials.

Instead of the protective layer 307, the organic EL elements may be protected from external water, oxygen, and contaminants by sealing an area around the element array with separately prepared glass. In the case where the EL elements are of the bottom emission type, the protective layer 307 may be formed of metal. Furthermore, the organic EL elements may be sealed with a metal plate instead of glass.

### Lens Array

The lens optical unit included in the lens array optical system 102 is described.

FIG. 4 is a sectional view of the lens optical system in the main and sub array directions. The lens optical unit includes the following three members arranged in a single optical path: a first lens 107 (hereafter referred to as G1), a light-shielding member 108, and a second lens 109 (hereafter referred to as G2). Every lens surface has a rectangular shape. As the lens array optical system 102, G1 and G2 each form an image in both the main and sub array directions.

With respect to the main array direction, a light beam emitted from a light source 104 passes through G1. After that, the light beam forms an image (hereafter referred to as an intermediate image forming plane 105) in the light-shielding member 108, passes through G2, and forms a unity-magnification erect image on an image plane 106. The light-shielding member 108 blocks part of the light beam directed to G2 of the lens optical unit in a different optical axis after the light beam has passed through G1.

### Optical Design of Lens

Here, optical design values of an example of the lens optical unit are shown in Table 1.

TABLE 1

| | | Aspheric surface | | | | |
|---|---|---|---|---|---|---|
| Light source wavelength | 780 nm | coefficient | G1R1 | G1R2 | G2R1 | G2R2 |
| G1 refractive index (light source wavelength) | 1.4859535 | C2, 0 | 0.5027743 | −0.8254911 | 0.8254911 | −0.5027743 |
| G2 refractive index (light source wavelength) | 1.4859535 | C4, 0 | −0.5125937 | 0.2916421 | −0.2916421 | 0.5125937 |
| Distance between object plane and G1R1 | 2.64997 mm | C6, 0 | −2.47 × 10⁻¹ | −0.5597057 | 0.5597057 | 0.2471568 |
| Distance between G1R1 and G1R2 | 1.25122 mm | C8, 0 | 0.08356994 | −0.01894198 | 0.01894198 | −0.08356994 |
| Distance between G1R2 and G2R1 | 2.16236 mm | C10, 0 | −6.92 × 10⁰ | −0.7824901 | 0.7824901 | 6.918249 |
| Distance between G2R1 and G2R2 | 1.25122 mm | C0, 2 | 0.1564267 | −0.1950417 | 0.1950417 | −0.1564267 |
| Distance between G2R2 and image plane | 2.64997 mm | C2, 2 | −0.1587308 | 0.09481253 | −0.09481253 | 0.1587308 |
| Effective diameter in intermediate image | 0.7 mm | C4, 2 | −0.1505496 | −0.3002326 | 0.3002326 | 0.1505496 |
| forming plane in main array direction | | | | | | |
| Magnification of intermediate imaging in | −0.45 | C6, 2 | 5.66 × 10⁰ | 3.065612 | −3.065612 | −5.659195 |
| main array direction | | | | | | |

| | | | | |
|---|---|---|---|---|
| C8, 2 | −13.83601 | −6.539772 | 6.539772 | 13.83601 |
| C0, 4 | −0.03678572 | −0.007561912 | 0.007561912 | 0.03678572 |
| C2, 4 | 0.1479884 | 0.03211153 | −0.03211153 | −0.1479884 |
| C4, 4 | −1.037058 | −0.5900471 | 0.5900471 | 1.037058 |
| C6, 4 | −1.894499 | −0.6987603 | −0.6987603 | 1.894499 |
| C0, 6 | 1.27 × 10⁻² | 0.001105971 | −0.001105971 | −0.01269685 |
| C2, 6 | −0.07714526 | −0.001013351 | 0.001013351 | 0.07714526 |
| C4, 6 | 9.71 × 10⁻¹ | 0.4132734 | −0.4132734 | −0.9714155 |
| C0, 8 | −0.006105566 | −0.00104791 | 0.00104791 | 0.006105566 |
| C2, 8 | −0.01341726 | −0.0182659 | 0.0182659 | 0.01341726 |
| C0, 10 | 0.001280955 | 9.61807 × 10⁻⁵ | −9.61807 × 10⁻⁵ | −0.001280955 |

It is defined that the intersection point of each lens surface and the optical axis is the origin, the optical axis direction is the X-axis, an axis perpendicular to the optical axis (X-axis) in a first direction is the Y-axis, and an axis perpendicular to the optical axis (X-axis) in a second direction is the Z-axis.

G1R1, G1R2, G2R1, and G2R2 surfaces are anamorphic aspheric surfaces and their aspheric surface shapes are expressed in the following expression (1).

X=ΣᵢⱼCᵢⱼYⁱZ^{j} (1)

where C_{i,j} (i,j=0, 1, 2 . . . ) is an aspherical surface coefficient.
Light Emitting Position with Respect to Lens Array

In the lens array optical system 102, since optical paths are different from one another in accordance with the light emitting positions, the light amount varies among images formed on the image plane 106. The principle of how the light amount varies among the formed images is specifically described below.

For simplicity of description, imaging light beams for the light emitting positions A, B, and C are described.

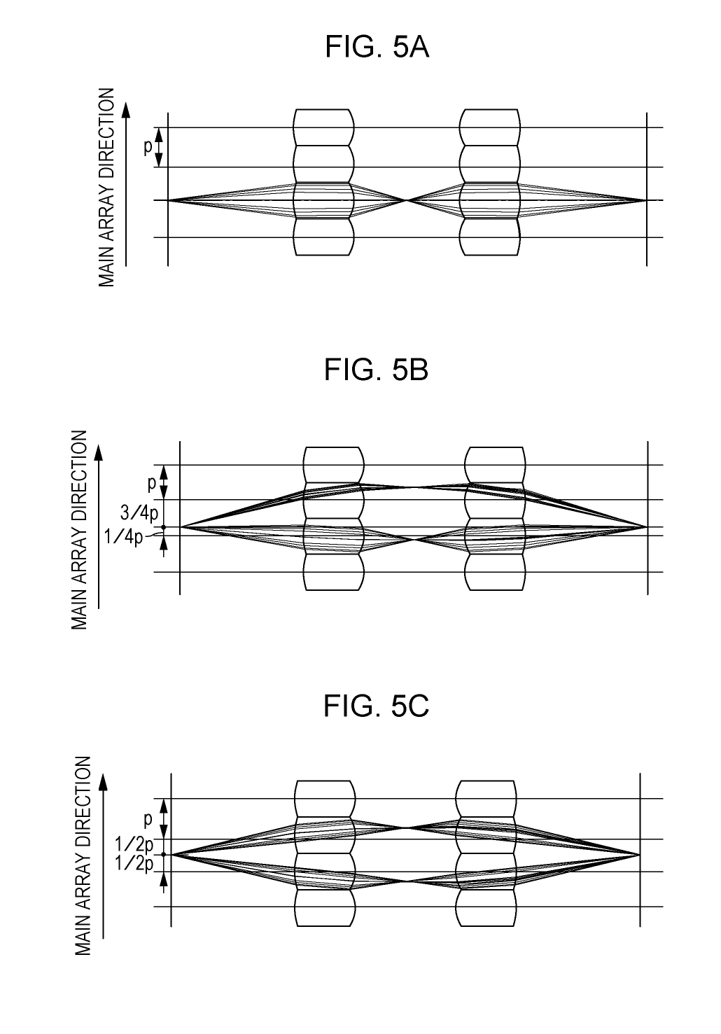

The light emitting position A is a position on the object plane, the position existing on the optical axis of the lens optical unit. FIG. 5A illustrates an imaging light beam of the light emitting position A. As can be seen from FIG. 5A, the imaging light beam includes only a 0 (on the optical axis) ray of a lens light beam of the lens optical unit.

The light emitting position B is separated from the light emitting position A in the main array direction by ¼ of an array pitch p of the lens optical unit. FIG. 5B illustrates an imaging light beam of the light emitting position B. As can be seen from FIG. 5B, the imaging light beam of the light emitting position B includes a ¼p ray of a lens light beam of the lens optical unit and a ¾p lens light beam of the lens optical unit.

The light emitting position C is separated from the light emitting position A in the main array direction by ½ of an array pitch p of the lens optical unit. FIG. 5C illustrates an imaging light beam of the light emitting position C. As can be seen from FIG. 5C, the imaging light beam includes two ½p rays of a lens light beam of the lens optical unit. Hereafter, the light emitting positions A, B, and C mean the same as those illustrated in FIGS. 5A to 5C in terms of the pitches or relationships with the optical axis of the lens optical unit.

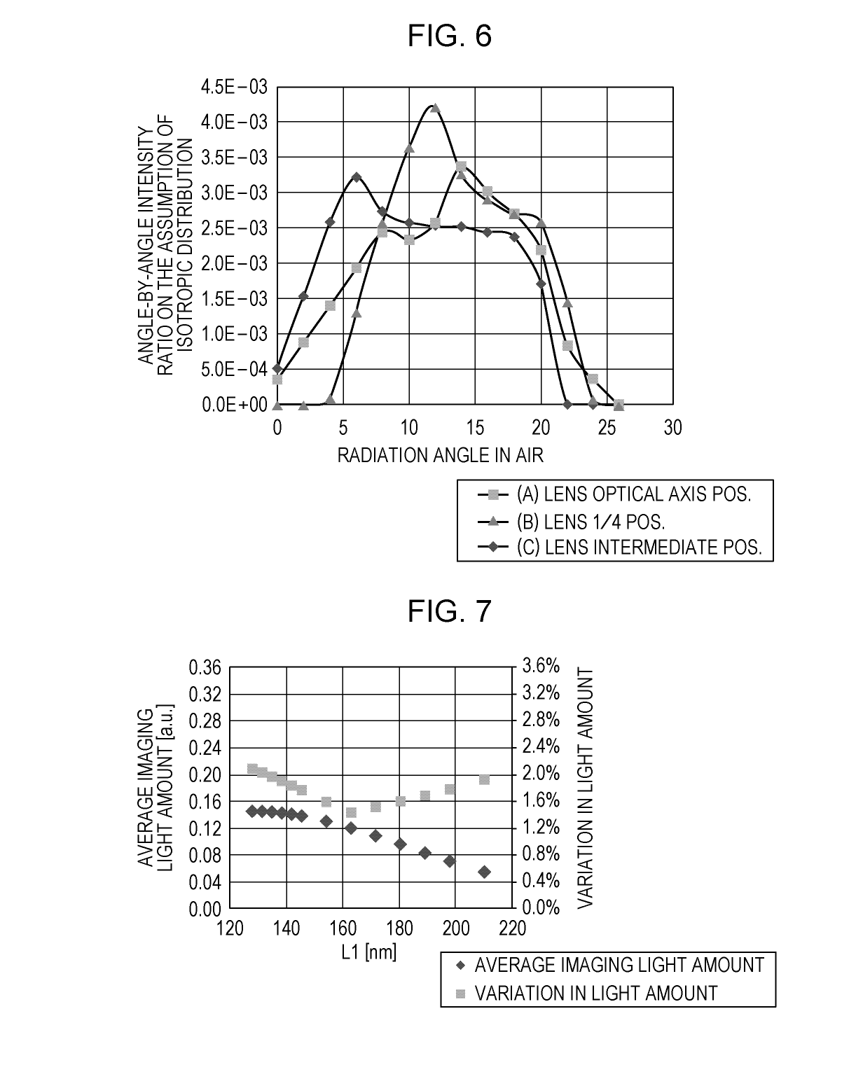

In FIG. 6, graphs A to C illustrate the angle-by-angle intensity ratio of the lens array optical system 102 on the assumption that the radiant intensity of the light emitting element is isotropically distributed in terms of the angle. The graphs are created from light ray diagrams in FIGS. 5A to 5C by setting the radiation angle of the light emitting element in air to the horizontal axis. In the case of the light emitting position A, which is immediately below the optical axis of the lens, the ray of the light beam emitted perpendicular (radiation angle: 0-degree) to the substrate is utilized. However, in the case of the light emitting position C, which is at a position immediately below a position between the lenses, rays of the light beams at or near the radiation angle 0-degree are not utilized. Regarding the light emitting positions B and C, the intensity ratio of the oblique rays at the radiation angle of 10 to 20-degrees is higher than that near the radiation angle of 0-degree. This indicates that, for the light emitting positions B and C of the present lens array optical system 102, light in the oblique direction contributes more to imaging than light in the perpendicular direction. It is also indicated that the rays at an angle larger than 26-degree do not contribute to imaging.

Variation in light amount is defined as the difference between the maximum and minimum imaging light amounts at the light emitting positions divided by an average value of the imaging light amounts. When the imaging light amounts of the light emitting positions A, B, and C are respectively denoted by K_{A}, K_{B}, and K_{C}, variation in light amount among the three light emitting positions A, B, and C is expressed by the following expression (2). Here, the average value of the imaging light amounts (K_{A}+K_{B}+K_{C})/3 is defined as an average imaging light amount.

(Max(K_{A},K_{B},K_{C})−Min(K_{A},K_{B},K_{C}))/((K_{A}+K_{B}+K_{C})/3) (2)

In the lens optical unit according to the present invention, it can be said that the light amount tends to vary due to the difference in the imaging light amount between the light emitting position A and the light emitting position B. The light emitting positions actually exist as many as the number of organic EL elements. Even in the case where four or more light emitting positions exist, according to the above-described definition of variation in light amount, variation in light amount can be obtained by dividing the difference between the maximum and minimum imaging light amounts at the light emitting positions by an average value of imaging light amounts.

Since the angular distribution of the radiant intensity of the organic EL elements changes due to interference, the value of variation in light amount changes in accordance with interference conditions. With an organic EL element, the radiation intensity of which significantly changes in accordance with the angle, the value of variation in light amount is often larger than that in the case where the isotropic distribution is assumed.

### First Embodiment

Here, suppression of variation in light amount due to an emission distribution according to a first embodiment is described in detail.

In general, the film thicknesses of the layers such as the light emitting layer included in the organic EL element are about tens of nm. Thus, the optical path length (product nd) calculated by multiplying the film thickness d of each layer by the corresponding refractive index n equals to about several tenths of the visible light wavelength (wavelength from 350 to 780 nm). Accordingly, multiple reflection and interference of visible light significantly occur in the organic EL element. A wavelength λ intensified by this interference effect (mutually intensifying wavelength λ due to optical interference) is defined by the following expression (3):

2L₁ cos θ=(m−φ₁/2π)λ (3)

L₁ is the optical path length between the light emitting position of the light emitting layer and the anode (reflective electrode) 303 (obtained by multiplying the physical film thickness d by the refractive index n; referred to as “optical path length L” hereafter). θ is the radiation angle in the light emitting layer, m is the order (integer equal to or greater than zero) of optical interference. When m=0, L becomes the minimum value that satisfies the expression (2). φ₁ is a phase shift amount in vertical reflection at the light reflective anode 303. The angle θ in the light emitting layer is in a one-to-one relationship with an angle in air by the Snell's law. Since the refractive index n_{EML} of the light emitting layer of the organic EL element is typically 1.7 to 1.8, which is higher than that of the air n_{Air} (=1.0), there exists a critical angle θC with air. In this case, both the refractive indices are in the relationship expressed by the following expression (4) according to the Snell's law:

n_{EML}×sin(θc)=n_{Air}×sin(π/2)=1 (4)

From the expression (2), the optical path length L(0) in the case where light of the wavelength λ is emitted while being intensified in the front direction (θ=0) is obtained by the following expression (5). The optical path length L (θc) in the case where light of the wavelength λ is emitted in a 90-degree direction in air is obtained by the following expression (6).

L₁(0)=(m−φ₁/2π)λ/2 (5)

L₁(θc)=(m−φ₁/2π)λ/(2 cos(θc)) (6).

Thus, in the case where the optical path length L₁ between the light emitting position of the light emitting layer and the anode 303 (reflective electrode) is in the following relationships,

L₁(0)<L₁<L₁(θc) (7),

this equals to a situation in which light of the wavelength λ is intensified in an oblique direction in air. Strictly speaking, the phase shift depends on the angle. However, since the oblique interference conditions can be generally described by the phase shift in perpendicular reflection, it can be said that, when the expression (7) holds, light of the wavelength λ is intensified in an oblique direction in air.

An object of the present invention is to suppress variation in light amount during light exposure by setting the optical path length so as to cause an interference, which intensifies the light of the wavelength λ, in the oblique direction (θ≠0). Thus, from the expressions (5) to (7), the optical path length L₁ between the light emitting position of the light emitting layer and the anode 303 (reflective electrode) satisfies the expression (8):

(m−φ₁/2π)λ/2<L₁<(m−φ₁/2π)λ/(2 cos(θc)) (8)

where φ₁ is the phase shift amount (in rad) when light emitted from the light emitting position is reflected by the anode 303, θc is a critical angle (in rad) relative to air in the organic EL element, λ is the maximum peak wavelength (in nm) of the light spectrum emitted from the light emitting layer, and m is an integer equal to or larger than zero.

Here, an example is specifically described. In the following example, the organic EL element includes: a light emitting material that emits light having a spectrum, the peak of which is at the wavelength λ of 600 nm; the organic EL layer 305 formed of an organic material, the refractive index of which at λ=600 nm is about 1.75; the cathode 306 on the light emitting side, which is a transparent conductive oxide layer formed of a light transmissive electrode such as indium zinc oxide; and the anode 303 on the light reflecting side formed of Al. The calculation result in the case where this organic EL element is combined with the lens array optical system 102 is described below. The optical calculation related to the organic EL element is performed in accordance with the contents described in M.S. Tomas and Z. Lenac, “Decay of excited molecules in absorbing planar cavities” Physical Review A, Vol. 56, (1997) p. 4197 or H. Benisty, R. Stanley, or M. Mayer, “Method of source terms for dipole emission modification in modes of arbitrary planar structures” Journal of the Optical Society of America A, Vol. 15, (1998) p. 1192. Values of the parameters in the present embodiment are shown in Table 2. The phase shift φ₁ is calculated from the optical constants (n, k) of the organic EL layer 305 and the anode 303. The critical angle θc is calculated in accordance with the Snell's law as described above. L₁(0) and L₁(θc) are calculated from the expressions (5) and (6).

TABLE 2

| | |
|---|---|
| m | 0 |
| λ [nm] | 600 |
| Refractive index of light emitting layer | 1.75 |
| φ1 [rad] | −2.68 |
| θc [rad] | 0.61 |
| L1(0) [nm] | 128 |
| L1(θc) [nm] | 156 |

The imaging light amount of the light emitting element at each of the light emitting positions A, B, and C can be calculated by superposing the angle-by-angle radiant intensity of each organic EL element and the corresponding angle-by-angle optical characteristic of the lens array optical system 102 on each other illustrated in FIG. 6. From the calculated imaging light amounts, the average imaging light amount and variation in light amount can be calculated in accordance with the definitions. FIG. 7 illustrates variation in light amount and the average imaging light amounts at the light emitting positions A, B, and C on the photosensitive body when changing the film thickness of the organic layer between the light emitting positions of the light emitting layer and the anode 303 on the light reflecting side.

Referring to FIG. 7, when L₁=128 nm, which is a condition under which the interference, which intensifies the light of the wavelength λ, is increased in the front direction, variation in light amount is 2.1%. When the optical path length L₁ is increased so as to cause the interference, which intensifies the light of the wavelength λ, in the oblique direction, variation in light amount is decreasing and reaches the minimum value near L₁=160 nm. In the present embodiment, it is illustrated that, since the condition under which the interference, which intensifies the light of the wavelength λ, is increased at the critical angle θc is L₁=156 nm, variation in light amount is more significantly suppressed by setting the optical path length so as to cause the interference, which intensifies the light of the wavelength λ, at an angle larger than the critical angle. However, when setting the optical path length so as to cause the interference, which intensifies the light of the wavelength λ, at an angle larger than the critical angle, the amount of light extracted to air decreases, thereby significantly decreasing the average imaging light amount. Thus, variation in light amount can be suppressed while setting the optical path length so as to satisfy the expression (7) with an angle smaller than the critical angle, the expression (7) representing the relationship in which the interference, which intensifies the light of the wavelength λ, is caused in the oblique direction.

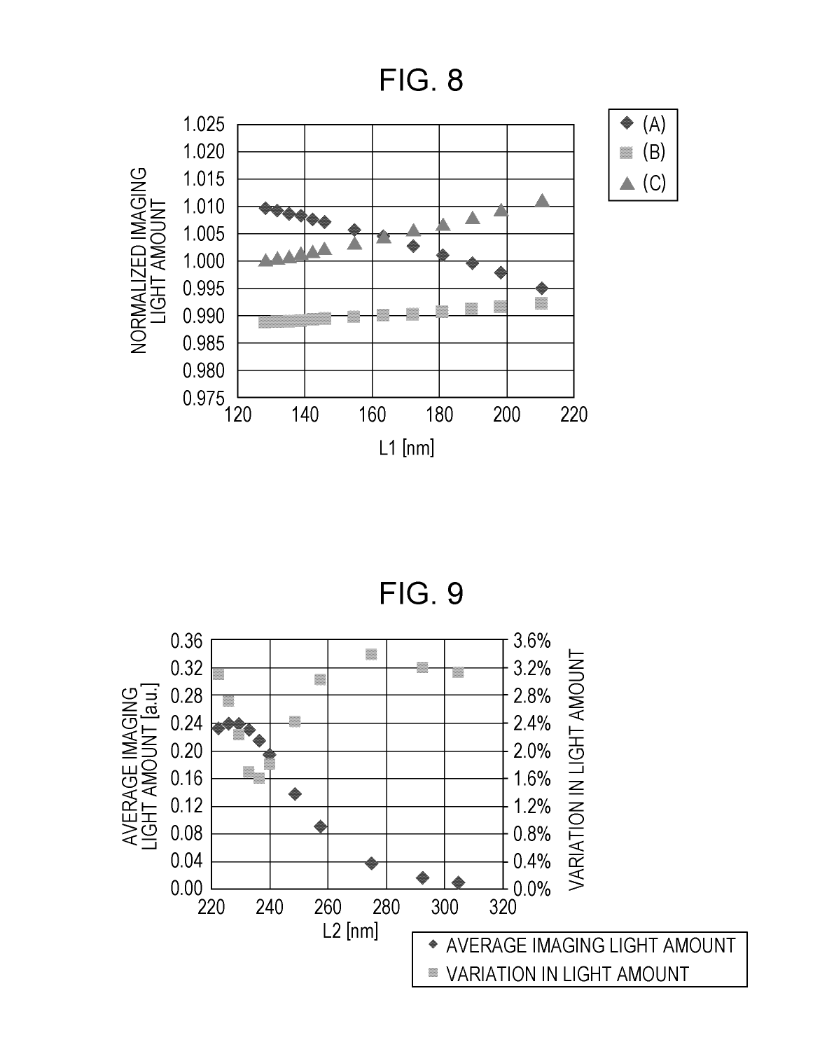

FIG. 8 illustrates comparison of the imaging light amount among the light emitting elements at the light emitting positions A, B, and C for explaining a mechanism that suppresses variation in light amount. In FIG. 8, since the imaging light amount is normalized based on the average imaging light amount at each angle, the difference in the maximum and minimum imaging light amounts at each angle equals to variation in light amount. FIG. 8 indicates that, when setting the optical path length so as to cause the interference, which intensifies the light of the wavelength λ, in the front direction, the imaging light amount is largest at the light emitting position A, and smallest at the light emitting position B. As described above, compared to the light emitting position A, imaging efficiency in the oblique direction is higher at the light emitting positions B and C. Thus, when the film thickness is increased so as to cause the interference, which intensifies the light of the wavelength λ emitted from the organic EL element, in the oblique direction, the ratio of the average light amount at the light emitting positions B and C is increased. Accordingly, the difference in light amount between the light emitting position A and the light emitting positions B or C is decreased when setting the optical path length so as to cause the interference, which intensifies the light of the wavelength λ, in the oblique direction. Thus, setting the optical path length so as to cause the interference, which intensifies the light of the wavelength λ, in the oblique direction is effective in order to decrease variation in light amount for light exposure with an optical writing device using a converging lens array.

Referring to FIG. 7, in the present embodiment, among the range of the values of L₁ that satisfy the expression (7), variation in light amount is minimum when L₁=156 nm. However, when variation in the film thickness of the organic EL element is considered, it is difficult to actually constantly produce the organic EL element, the film thickness of the organic layer of which minimizes variation in light amount. Accordingly, it is preferable that L₁ be within a ±10% range of the optical path length at which variation in light amount is minimized, and more preferable that L₁ be within a ±5% range of the optical path length at which variation in light amount is minimized. In the present structure, since the optical path length at which variation in light amount is minimized is 160 nm, it is preferable that L₁ be from 144 to 176 nm. Actually, when 144 nm≦L₁≦176 nm is satisfied and the optical path length is set so as to cause the interference, which intensifies the light of the wavelength λ, in the oblique direction, variation in light amount can be reduced more than the case of using the condition L₁(0), where the optical path length is set so as to cause the interference, which intensifies the light of the wavelength λ, in the front direction, the condition being generally used for organic EL elements in many cases.

Referring again to FIG. 7, the average imaging light amount is higher in a range of the optical path length smaller than the optical path length at which variation in light amount is minimized. Accordingly, from the viewpoint of having a large average imaging light amount and minimizing variation in light amount, within a ±10% range of the optical path length at which variation in light amount is minimized, the optical path length can be smaller than the optical path length at which variation in light amount is minimized. Thus, in the present embodiment, the average imaging light amount is large and variation in light amount is minimized when L₁ is in the following range: 144 nm≦L₁≦156 nm. The minimum value of variation in light amount and an interference angle at which variation in light amount is minimized vary in accordance with the optical characteristics of the converging lens array and interference intensity of the organic EL element.

### Second Embodiment

Next, in order to observe a change in variation in light amount in accordance with the interference intensity, the cathode 306 on the light emitting side of the organic EL element is changed from that of the first embodiment to a semi-transparent electrode formed of Ag (20 nm). This organic EL element is combined with the lens array optical system 102. The calculation result is described below. In the case where the organic EL element uses a metal thin film as the electrode on the light emitting side, interference between both the electrodes is increased. Thus, the optical path length L₂ between both the electrodes significantly affects the characteristics of the light emitting element. In order to significantly extract light in the oblique direction in air by adjusting L₂, it is sufficient that the expression (9) be satisfied.

(n−φ₂/2π)λ/2<L₂<(n−φ₂/2π)λ/(2 cos(θc)) (9)

where φ₂ is the sum of the phase shift amounts (in rad) when light emitted from the light emitting position of the light emitting layer is reflected by the first and second electrodes at an angle θ, and n is an integer equal to or larger than zero.

Values of the parameters in the present embodiment are shown in Table 3. The phase shift φ₂ is calculated from the optical constants (n, k) of the organic EL layer 305, the reflective anode 303, and the cathode 306 on the light emitting side. The critical angle θc is calculated in accordance with the Snell's law as described above. L₂(0) and L₂(θc) correspond to the left-hand side and the right-hand side of the expression (9), respectively.

TABLE 3

| | |
|---|---|
| m | 0 |
| λ [nm] | 600 |
| Refractive index of light emitting layer | 1.75 |
| φ2 [rad] | −4.65 |
| θc [rad] | 0.61 |
| L2(0) [nm] | 222 |
| L2(θc) [nm] | 271 |

The imaging light amount of the light emitting element at each of the light emitting positions A, B, and C can be calculated by superposing the angle-by-angle radiant intensity of each organic EL element and the corresponding angle-by-angle optical characteristic of the lens array optical system 102 on each other illustrated in FIG. 6. FIG. 9 illustrates the relationship between variation in light amount and the average imaging light amounts at the light emitting positions A, B, and C on the photosensitive body at that time as the optical path length L₂ between the anode 303 and the cathode 306 is varied by changing the film thickness of the organic layer between the light emitting positions of the light emitting layer and the anode 303 on the light reflecting side.

Referring to FIG. 9, when L₂=222 nm, which is a condition under which the interference, which intensifies the light of the wavelength λ, is increased in the front direction, variation in light amount is 3.1%. When the optical path length L₂ is increased so as to cause the interference, which intensifies the light of the wavelength λ, in the oblique direction, variation in light amount is decreasing and reaches the minimum value near L₂=236 nm. In a structure in which a semi-transparent film is used on the light extracting side, interference is increased. As a result, the average imaging light amount in the case where the optical path length is set so as to cause the interference, which intensifies the light of the wavelength λ, in the front direction is increased while variation in light amount is increased. Furthermore, when interference is increased, changes in the average imaging light amount and variation in light amount are increased in the case where the interference angle is changed by the optical path length.

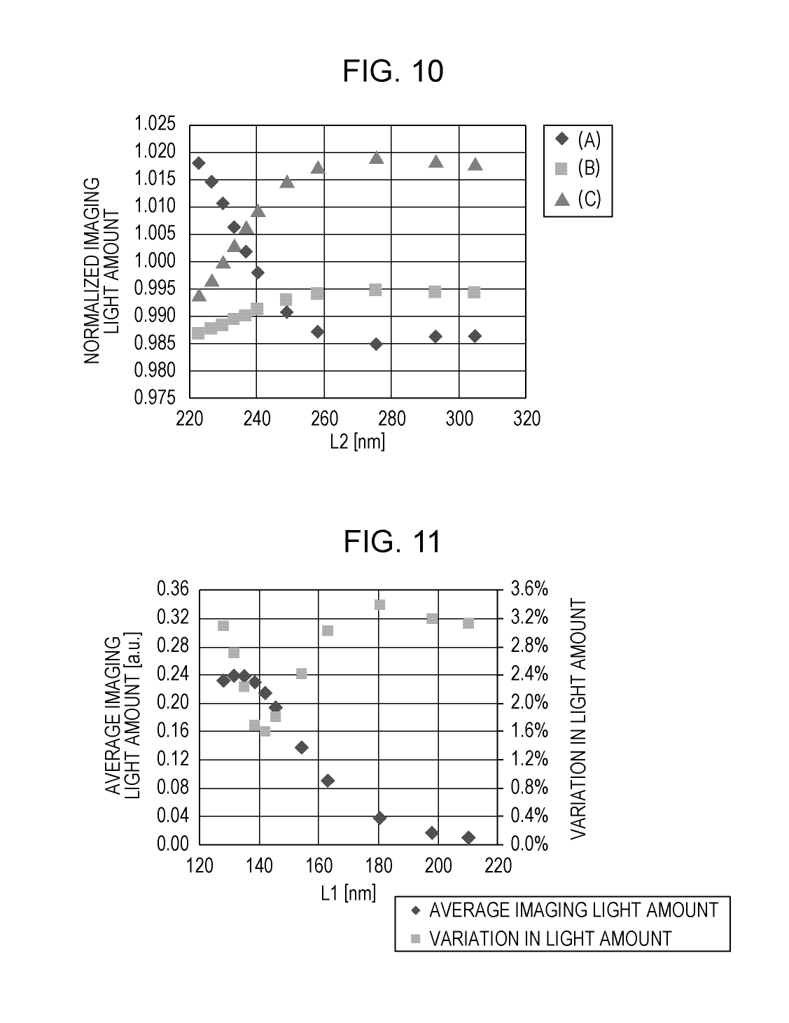

FIG. 10 illustrates the imaging light amount of the light emitting element normalized based on the average imaging light amounts at each angle. FIG. 10 indicates that, when setting the optical path length so as to cause the interference, which intensifies the light of the wavelength λ, in the front direction, the imaging light amount is largest at the light emitting position A, and smallest at the light emitting position B. As described above, compared to the light emitting position A, imaging efficiency in the oblique direction is higher at the light emitting positions B and C. Thus, when the film thickness is increased so as to cause the interference, which intensifies the light of the wavelength λ emitted from the organic EL element, in the oblique direction, the ratio of the average light amount at the light emitting positions B and C is increased. Accordingly, the difference in light amount between the light emitting position A and the light emitting positions B or C is decreased when setting the optical path length so as to cause the interference, which intensifies the light of the wavelength λ, in the oblique direction. Thus, setting the optical path length so as to cause the interference, which intensifies the light of the wavelength λ, in the oblique direction is effective in order to decrease variation in light amount for light exposure with an optical writing device using a converging lens array.

Referring to FIG. 9, in the range of the values of L₂ that satisfy the expression (9), variation in light amount is minimum when L₂=236 nm. As is the case with the present embodiment in which the organic EL elements for significant interference is used, changing interference significantly affects the optical characteristics. Thus, it is preferable that L₂ be an optical path length within ±5% of the optical path length at which variation in light amount is minimized. The ±5% of the optical path length at which variation in light amount is minimized is from 225 to 247 nm. In this case, variation in light amount can be reduced more than the case of using the condition L₂(0), where the optical path length is set so as to cause the interference, which intensifies the light of the wavelength λ, in the front direction, the condition being generally used for organic EL elements in many cases.

By using the present invention, variation in light amount can be reduced more than an embodiment where the optical path length is set so as to cause the interference, which intensifies the light of the wavelength λ, in the front direction, the embodiment being generally used for organic EL elements in many cases. Since the characteristics of the organic EL element for significant interference are significantly changed in accordance with the view angle. Thus, variation in light amount is increased. Accordingly, the present invention is particularly effective for an element of significant interference that uses a metal semi-transparent film for the electrode on the light emitting side. Regarding the difference between variation in light amount in the case where the optical path length is set so as to cause the interference, which intensifies the light of the wavelength λ, in the front direction and the minimum value of variation in light amount, the difference is 0.66% in the first embodiment for insignificant interference while the difference is 1.49% in the second embodiment for significant interference. This also clarifies that the present invention is particularly effective for an element for significant interference. Here, an element for significant interference refers to an element that has a semi-reflective surface having a reflectance of 30% or more on the light emitting side with respect to the light emitting layer. The semi-reflective surface can be obtained by using a dielectric mirror, in which a plurality of high refractive index and low refractive index layers are stacked one on top of another, in addition to using a metal semi-transparent film.

Furthermore, it is preferable that the optical path length L₂ be an optical path length within ±5% of the optical path length at which the average imaging light amount is maximized. It can be seen from FIG. 9 that, in the present embodiment, the average imaging light amount is maximum when L₂=226 nm. Thus, an optical path length within ±5% of the optical path length at which the average imaging light amount is maximized is from 215 to 237 nm. That is, the optical path length L₂ is preferably set in a range from 225 to 237 nm. Here, the average imaging light amount is larger in the case where L₂=226 nm than in the case where L₂=222 nm, which is the condition under which the interference, which intensifies the light of the wavelength λ, in the front direction is increased. The reason for this is that, as illustrated in FIG. 6, imaging efficiency of the lens array optical system is higher in the oblique direction than in the front direction.

Also in the present embodiment, the expression (8) described above can be satisfied. FIG. 11 is a graph in which the horizontal axis represents the optical path length L₁ between the light emitting position of the light emitting layer and the anode 303 (reflective electrode), and the vertical axis represents the average imaging light amount and variation in light amount in the present embodiment. Since, in the present embodiment, the structure from the anode 303 (reflective electrode) to the light emitting layer is the same as that of the first embodiment, the values of the parameters are the same as those of Table 1. Referring to FIG. 11, the average imaging light amount is maximum when L₁=131 nm, and variation in light amount is minimum when L₁=142 nm. These maximum and minimum values are in a range between L₁(0)=128 nm and L₁(θc)=156 nm. Thus, it is confirmed that optimum solutions of the average imaging light amount and the variation in light amount exist in the expression (8) of the present invention, the expression for causing the interference, which intensifies the light of the wavelength λ, in the oblique direction. Furthermore, in the organic EL element, the optical path length L₁ between the light emitting position of the light emitting layer and the anode 303 is preferably an optical path length within ±5% of the optical path length at which variation in light amount during light exposure is minimized. Also regarding the average imaging light amount, the optical path length within ±5% of the optical path length L₁ or L₂ at which the average imaging light amount is maximized is preferable.

In the case where the cathode 306 uses a dielectric mirror, similarly to the case where the cathode 306 uses a metal thin film, the optical path length L₂ between both the electrodes significantly affects the characteristics of the light emitting element. Thus, the expression (9) can be satisfied. As the structure of the dielectric mirror, any of known structures can be used. As typical examples of the structure include a multilayer formed of TiO₂ as a high refractive index material and SiO₂ or MgF₂ as a low refractive index layer, which are alternately stacked one on top of another.

For convenience of description in the embodiments described above, variation in light amount at three positions has been discussed. However, the light emitting positions actually exist as many as the number of organic EL elements. Even in the case where four or more light emitting positions exist, according to the above-described definition of variation in light amount, variation in light amount can be obtained by dividing the difference between the maximum and minimum imaging light amounts at the light emitting positions by an average value of imaging light amounts.

Although the embodiments described above are of a top emission type, the present invention is useful to a bottom emission type. There is no particular restriction regarding the emission wavelength and emission spectrum. The present invention can be applied to organic EL elements that emit light at a wavelength in a green or blue spectrum bands.

In some cases of related art, a lens array is fabricated on an element array formation substrate. However, in this case, light, which otherwise is confined in an organic EL element, is extracted by the lens array, thereby increasing variation in light amount during light exposure. For this reason, the lens array can be separated from the element array.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-222888, filed Oct. 5, 2012 and Japanese Patent Application No. 2013-188028, filed Sep. 11, 2013, which are hereby incorporated by reference herein in their entirety.

### REFERENCE SIGNS LIST

17, 18, 19, 20 exposure device
303 anode
305 organic EL layer
306 cathode

1. An exposure device comprising:
an element array that includes a plurality of organic electroluminescent elements; and
a lens array optical system that uses a lens array that includes a plurality of lenses, the lenses forming images of light from the element array on a photosensitive body,
wherein each electroluminescent element has a first electrode disposed on a light emitting side, a second electrode disposed on a light reflecting side, and a light emitting layer, and
wherein, in each organic electroluminescent element, an optical path length L₁ between a light emitting position of the light emitting layer and the second electrode is an optical path length within ±10% of an optical path length at which variation in light amount during light exposure is minimized.

2. The exposure device according to claim 1,
wherein the optical path length L₁ is an optical path length within ±5% of the optical path length at which variation in light amount during light exposure is minimized.

3. The exposure device according to claim 1,
wherein the optical path length L₁ satisfies the following expression:
(m−φ₁/2π)λ/2<L₁<(m−φ₁/2π)λ/(2 cos(θc))
where φ₁ is a phase shift amount in radians when light emitted from the light emitting position is reflected by the second electrode, θc is a critical angle in radians relative to air in the organic electroluminescent element, λ is a maximum peak wavelength in nm of a light spectrum emitted from the light emitting layer, and m is an integer equal to or larger than zero.

4. The exposure device according to claim 1,
wherein the optical path length L₁ is smaller than the optical path length at which variation in light amount during light exposure is minimized.

5. The exposure device according to claim 1,
wherein the first electrode is formed of a transparent conductive oxide layer.

6. An exposure device comprising:
an element array that includes a plurality of organic electroluminescent elements; and
a lens array optical system that uses a lens array that includes a plurality of lenses, the lenses forming images of light from the element array on a photosensitive body,
wherein each electroluminescent element has a first electrode disposed on a light emitting side, a second electrode disposed on a light reflecting side, and a light emitting layer,
wherein the first electrode has a metal film or a dielectric mirror, and
wherein, in each organic electroluminescent element, an optical path length L₂ between the first electrode and the second electrode is an optical path length within ±5% of an optical path length at which variation in light amount during light exposure is minimized.

7. The exposure device according to claim 6,
wherein the optical path length L₂ satisfies the following expression:
(n−φ₂/2π)λ/2<L₂<(n−φ₂/2π)λ/(2 cos(θc))
where φ₂ is a sum of phase shift amounts in radians when light emitted from the light emitting position is reflected by each of the first and second electrodes, θc is a critical angle in radians relative to air in the organic electroluminescent element, λ is a maximum peak wavelength in nm of a light spectrum emitted from the light emitting layer, and n is an integer equal to or larger than zero.

8. The exposure device according to claim 6,
wherein the optical path length L₂ is smaller than the optical path length at which variation in light amount during light exposure is minimized.

9. The exposure device according to claim 6,
wherein the optical path length L₂ is an optical path length within ±5% of an optical path length at which an average imaging light amount is maximized.

10. The exposure device according to claim 6,
wherein, in each organic electroluminescent element, the optical path length L₁ between the light emitting position of the light emitting layer and the second electrode is the optical path length within ±5% of the optical path length at which variation in light amount during light exposure is minimized.

11. The exposure device according to claim 6,
wherein the optical path length L₁ satisfies the following expression:
(m−φ₁/2π)λ/2<L₁<(m−φ₁/2π)λ/(2 cos(θc))
where φ₁ is a phase shift amount in radians when light emitted from the light emitting position is reflected by the second electrode, θc is a critical angle in radians relative to air in the organic electroluminescent element, λ is a maximum peak wavelength in nm of a light spectrum emitted from the light emitting layer, and m is an integer equal to or larger than zero.

12. The exposure device according to claim 1,
wherein the element array and the lens array are separated from each other.

13. An image forming apparatus comprising:
the exposure device according to claim 1;
a photosensitive body, a latent image is formed on a surface of the photosensitive body by using the exposure device; and
a charging unit that charges the photosensitive body.
